(19) United States
(12) Patent Application Publication
(10) Pub. No.: US 2003/0095674 A1
(43) Pub. Date: May 22, 2003

(54) Microphone system for the fueling environment

(75) Inventor: Tommy W. Lewis, Chesapeake, VA (US)

Correspondence Address: RANDALL J. KNUTH P.C., 3510-A STELLHORN ROAD, FORT WAYNE, IN, 46815-4631, US

(73) Assignee: Tokheim Corporation

(21) Appl. No.: 09/996,405

(22) Filed: Nov. 20, 2001

(51) Int. Cl. H04R 3/00; H03G 3/20

(52) U.S. Cl. 381/110

(57) ABSTRACT

A refueling environment includes a fuel dispenser position having an intercom system that comprises a speaker unit and a microphone unit. The dispenser microphone unit includes an array of directional microphones defining an acoustic coverage pattern tailored to receive voice communications uttered by a customer. A voice-activatable fuel dispenser controller may receive voice-based command signals from the dispenser microphone unit. A POS terminal in the refueling environment includes an intercom system having a speaker unit and a microphone unit. The POS microphone unit includes an array of directional microphones defining an acoustic coverage pattern configured to receive voice communications uttered by a station operator. A packet-based data network provides a communications link between the dispenser intercom system and POS intercom system to establish a voice connection therebetween that supports a Voice over Internet Protocol (VoIP) format.

### CROSS-REFERENCE TO RELATED APPLICATIONS

This application is related to U.S. patent application Ser. No. 09/976,308 entitled “METHOD AND APPARATUS FOR IMPLEMENTING VOICE OVER INTERNET PROTOCOL IN THE REFUELING ENVIRONMENT” filed Oct. 11, 2001 and assigned to the same assignee as the present application, which is incorporated herein by reference thereto.

### BACKGROUND OF THE INVENTION

1. Field of the Invention

The present invention relates to a refueling environment, and, more particularly, to an intercom system disposed at a fuel dispenser position and including a microphone assembly having an array of directional microphones.

2. Description of the Related Art

Fuel dispenser locations are typically configured with user interactive terminals that enable refueling customers to conduct various tasks related to the dispensing operation. For example, a user terminal may include a card reader device that allows the customer to submit payment information in the form of a credit or debit card transaction. Payment data is forwarded to an on-site point-of-sale (POS) terminal that proceeds with an authorization check. The dispensing operation may then commence once the transaction has been approved.

The POS terminal is typically manned by operator personnel who monitor the various dispensing operations. In some scenarios, the personnel are required to interact with the customer to field various questions, provide refueling instructions, or otherwise direct proper use of the dispenser equipment by the customer.

For this purpose, suitable communication equipment may be installed that provides a communications channel between the dispenser position and POS terminal. For example, a microphone may be used at the dispenser position to transmit voice signals from the user to the POS terminal, which will receive and reproduce the voice communication using a conventional speaker device.

However, conventional microphone arrangements located at the fuel dispenser side employ an omni-directional microphone configuration that collects significant unwanted audio signals other than the speech utterances of the customer. This interference degrades the quality of the customer voice signal and can result in an audio output that is unintelligible or otherwise imperceptible to the POS terminal operator. Clearly, the inability of the operator to discern the speech of the customer adversely affects customer service and needlessly prolongs the transaction.

The presence of background noise at the dispenser position is unavoidable because the refueling location is situated in an external, open-air environment that has no type of shielding or other such partitioning structure that might serve as a sound barrier. A sound-proof enclosure that houses the dispenser position would alleviate the interference problem, but this option is neither feasible nor practicable.

Another feature of omni-directional microphone reception concerns the lack of discrimination in regards to the collection of audio signals from all point source locations, regardless of their spatial relationship to the microphone. For example, an omni-directional microphone positioned at the fuel dispenser may acquire audio signals that emanate from an audio source located above or behind the fuel dispenser. However, these audio signals are useless since no meaningful audio signal will originate from above or behind the dispenser. The only relevant audio signals are those uttered by the customer, who is stationed in front of the microphone terminal.

Additionally, conventional refueling equipment that is voice-based or otherwise voice-activated is prone to operating errors to the extent that it relies upon voice commands uttered into an omni-directional microphone. In particular, since the voice quality may be seriously impaired by extraneous sounds collected along with the customer speech, a voice-activated dispenser controller may be unable to interpret the voice-based command that it receives from the microphone.

In some cases, the dispenser may be susceptible to improper operation if the controller misinterprets the voice-based commands and instructs the dispenser to conduct an unrequested operation. It is vital, therefore, that a robust, high-performance voice channel be provided between the microphone assembly and any voice-activatable equipment, especially important machinery such as a fuel pump controller.

### SUMMARY OF THE INVENTION

According to the present invention there is provided a refueling environment having at least one fuel dispenser position. One or more of the dispenser positions includes a respective microphone unit comprising an array of directional microphones. The microphone array defines an acoustic coverage pattern that is configured to receive voice communications uttered by a customer. In particular, the acoustic coverage pattern encompasses at least the spatial area proximate the fuel dispenser where it is expected that the customer will be positioned while uttering voice communications directed at the microphone unit.

A processing unit is provided to process microphone signals generated by the directional microphones of the dispenser microphone unit. Various strategies may be used to implement the signal processing function, such as software-based algorithms that are programmed to furnish an optimal acoustic output.

In one illustrative form, the processing algorithm may produce a composite signal based upon a weighted sum combination of the individual audio signals received by the various directional microphones. The composite signal is then transmitted to the recipient or end user destination, e.g., a speaker at the POS terminal.

In an alternate form, the processing algorithm may determine which one of the individual microphone signals optimally satisfies a predetermined performance evaluation criteria, such as signal-to-noise ratio. A functional voice connection will then be established between the end user and the particular one of the directional microphones that is associated with the optimal performance determination. The individual microphone signals are continuously evaluated and analyzed on a real-time, dynamic basis so that the microphone signal representing the best acoustic reception is routed to the end user, thereby providing an adaptive voice connection. In this manner, the voice connection effectively switches among the multiple microphones as the source of optimal reception varies across different ones of the microphones.

The dispenser position also preferably includes a speaker unit in combination with the microphone unit to form an intercom system. The dispenser position also may include a voice-activatable fuel dispenser controller that receives voice-based command signals from the dispenser microphone unit.

A POS terminal in the refueling environment includes an intercom system having a speaker unit and a microphone unit. The POS microphone unit likewise preferably includes an array of directional microphones defining an acoustic coverage pattern that is configured to receive voice communications uttered by a station operator.

A packet-based data network provides a communications link between the dispenser intercom system and POS intercom system to establish a voice connection therebetween that supports a Voice over Internet Protocol (VoIP) format.

The invention, in one form thereof, is directed to a system for use with a fuel dispenser position in a refueling environment. The system includes, in combination, a microphone assembly disposed at the fuel dispenser position and a processing assembly operatively associated with the microphone assembly. The microphone assembly includes a plurality of directional microphones. The processing assembly is configured to process signals operatively generated by the directional microphones of the microphone assembly. In one preferred form, the directional microphones are arranged to define a desired acoustic coverage pattern.

In one exemplary form, the processing assembly is configured to form a composite signal using signals from at least two directional microphones of the microphone assembly. The system further includes an operator facility and a means to direct the composite signal formed by the processing assembly to the operator facility.

In another exemplary form, the processing assembly is configured to determine which microphone signal among the signals operatively generated by the directional microphones optimally satisfies a predetermined performance criteria. The system further includes an operator facility and a means to direct the microphone signal operatively associated with the optimal performance determination to the operator facility.

The system, in one alternate form, further includes an operator facility including a plurality of directional microphones, and a coupling means to provide operative coupling between the operator facility and the fuel dispenser position to enable communication therebetween. The system further includes a first speaker system disposed at the fuel dispenser position, and a second speaker system disposed at the operator facility. The coupling means is then configured to enable communication between the directional microphones of the microphone assembly and the second speaker system, and to enable communication between the directional microphones of the operator facility and the first speaker system.

The system, in another alternate form, further includes a fuel dispenser apparatus disposed at the fuel dispenser position, and a dispenser controller configured to operatively control the fuel dispenser apparatus in response to at least one command signal. The processing assembly is configured further to operatively process at least one microphone signal and to generate therefrom at least one command-type signal for use by the dispenser controller.

The system, in another alternate form, further includes a voice-activatable fuel dispenser system disposed at the fuel dispenser position and operatively associated with the microphone assembly.

The system, in yet another alternate form, further includes a packet-based data network configured for connection to at least one of the microphone assembly and the processing assembly.

In another exemplary form, the processing assembly is configured further to operatively provide processed microphone signals in an Internet Protocol (IP) format.

The invention, in another form thereof, is directed to a system comprising, in combination, a refueling environment including a fuel dispenser position, an operator facility in the refueling environment, and a coupling means configured to provide operative coupling between the fuel dispenser position and the operator facility. The fuel dispenser position includes a microphone system having a plurality of directional microphones.

The system further includes a processing system configured to process signals operatively generated by the directional microphones of the microphone system.

In one form, the processing system is configured further to form a composite signal using signals from at least two directional microphones of the microphone system. A means is provided to direct the composite signal to the operator facility using the coupling means.

In another form, the processing system is configured further to determine which microphone signal among the signals operatively generated by the directional microphones of the microphone system optimally satisfies a predetermined performance criteria. A means is provided to direct the microphone signal operatively associated with the optimal performance determination to the operator facility.

The operator facility further includes a plurality of operator-related directional microphones and a processing unit configured to process signals operatively generated by the plurality of operator-related directional microphones. The operator facility includes a point-of-sale (POS) terminal.

The system, in one alternate form, further includes a voice-activatable fuel dispenser system disposed at the fuel dispenser position and operatively associated with the microphone system.

The invention, in another form thereof, is directed to a system for use in a refueling environment having a fuel dispenser position and an operator facility. The system includes, in combination, a dispenser intercom system disposed proximate the fuel dispenser position and an operator intercom system disposed proximate the operator facility. A coupling means is configured to provide operative coupling between the dispenser intercom system and the operator intercom system. The dispenser intercom system includes a first speaker system and a first microphone system comprising a plurality of directional microphones. The operator intercom system includes a second speaker system and a second microphone system.

The system further includes a first processor operatively associated with the dispenser intercom system. The first processor is configured to process signals operatively generated by the directional microphones of the first microphone system.

In one form, the first processor is configured further to form a composite signal using signals from at least two directional microphones of the first microphone system, and to direct the composite signal to the operator intercom system using the coupling means.

In another form, the first processor is configured further to determine which microphone signal among the microphone signals operatively generated by the first microphone system optimally satisfies a predetermined performance criteria, and to direct the microphone signal operatively associated with the optimal performance determination to the operator intercom system using the coupling means.

In yet another form, the first processor is configured further to operatively provide processed microphone signals in an Internet Protocol (IP) format.

The system, in one alternate form, further includes a fuel dispenser apparatus disposed at the fuel dispenser position, and a dispenser controller configured to operatively control the fuel dispenser apparatus in response to at least one command signal. The first processor is configured further to process at least one microphone signal operatively generated by the first microphone system and to generate therefrom at least one command-type signal for use by the dispenser controller.

The second microphone system of the operator intercom system includes a plurality of directional microphones. A second processor operatively associated with the operator intercom system is configured to process signals operatively generated by the directional microphones of the second microphone system.

The operator facility includes a point-of-sale (POS) terminal. The coupling means includes a packet-based data network. The system further includes a voice-activatable fuel dispenser system disposed at the fuel dispenser position and operatively associated with the first microphone system.

The invention, in another form thereof, is directed to a system for use in a refueling environment having a fuel dispenser position and also for use in combination with an operator facility. The system includes, in combination, a first communication system disposed at the fuel dispenser position, and a communications link configured to enable operative communications between the first communication system and the operator facility. The first communication system includes a first microphone system and a first speaker system. The first microphone system includes a plurality of directional microphones.

In one form, the communications link is configured further to enable the first microphone system to transmit microphone signals operatively generated thereby to the operator facility, and to enable the first speaker system to receive audio-related signals from the operator facility.

In one form, the communications link includes a packet-based data network.

In one alternate form, the operator facility is disposed remote from the refueling environment. In another alternate form, the operator facility is disposed in the refueling environment and includes a point-of-sale (POS) terminal.

The system further includes a first processor operatively associated with the first communication system. The first processor is configured to process signals operatively generated by the directional microphones of the first microphone system in accordance with a predetermined processing function.

In one alternate form, the predetermined processing function performed by the first processor is defined by the formation of a composite signal using signals from at least two directional microphones of the first microphone system. In another alternate form, the predetermined processing function is defined by a determination of which microphone signal among the signals operatively generated by the directional microphones of the first microphone system optimally satisfies a predetermined performance criteria.

One advantage of the present invention is that the dispenser-resident directional microphones are capable of defining a predetermined audio receiving space having the highest probability of acquiring customer voice communications while limiting the amount of extraneous audio interference and noise.

Another advantage of the invention is that the directional microphones are selectively configured to define an optimal beam coverage pattern that takes into account the full range of expected positions that a customer may assume while emitting speech communications.

Another advantage of the invention is that the integrity and quality of audio communications between the customer and station operator may be vastly improved by the use of individual directional microphone systems installed at both the dispenser position and POS terminal.

Another advantage of the invention is that various programmable-type algorithmic strategies may be used to process and analyze the directional microphone output signals in a manner calculated to optimize the audio reception.

Another advantage of the invention is that the deployment of a microphone system having an array of individual microphone devices having distinctive coverage patterns enables a computer-based processor to determine which microphone provides the best reception, effectively providing a “steering” or tracking capability that allows the system to spatially “track” the customer voice by dynamically switching among the microphones depending upon which one has the best reception.

Another advantage of the invention is that advanced digital signal processing and microprocessor techniques (e.g., Application Specific Integrated Circuits) may be used to further enhance the quality of the voice signals received by the directional microphones.

Another advantage of the invention is that the problems attending the use of conventional omni-directional microphones are overcome and otherwise avoided by the use of directional microphones.

Another advantage of the invention is that the directional microphone system may be integrated with advanced communication facilities such as packet-based data networks to facilitate the development of a Voice over Internet Protocol (VoIP) functionality within the refueling environment.

A further advantage of the invention is that the dispenser-based directional microphone system will improve the reliability of voice-activated fuel dispenser equipment since the directional microphones will provide a clearer, unambiguous, and more distinctive voice signal that can be readily and easily interpreted by the dispenser controller and translated into a correspond control signal.

Another advantage of the invention is that a voice-activatable fuel dispenser that receives voice-based commands from a directional microphone assembly is not susceptible to committing interpretation errors of the type that affect conventional arrangements employing omni-directional microphones.

### BRIEF DESCRIPTION OF THE DRAWINGS

The above-mentioned and other features and advantages of this invention, and the manner of attaining them, will become more apparent and the invention will be better understood by reference to the following description of an embodiment of the invention taken in conjunction with the accompanying drawings, wherein:

FIG. 1 is a block diagram schematic view of an illustrative fuel dispenser position employing a directional microphone system, according to one example of the present invention;

FIG. 2 is a block diagram schematic view of an illustrative signal processing unit for use in analyzing the directional microphone signals generated by the system shown in FIG. 1; and

FIG. 3 is a block diagram schematic view of an illustrative configuration for a refueling environment that employs respective intercom systems at the dispenser position and POS terminal.

Corresponding reference characters indicate corresponding parts throughout the several views. The exemplification set out herein illustrates one preferred embodiment of the invention, in one form, and such exemplification is not to be construed as limiting the scope of the invention in any manner.

### DETAILED DESCRIPTION OF THE INVENTION

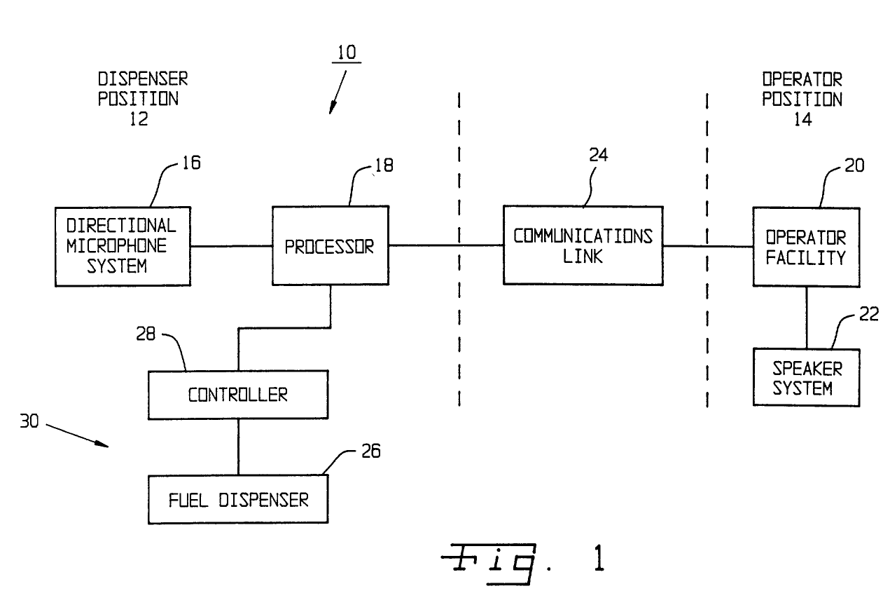

Referring now to the drawings and particularly to FIG. 1, there is shown in block diagram format a refueling environment 10 including a representative dispenser position 12 and a representative operator position 14, according to one example of the present invention. Although only a single dispenser position 12 is shown, it should be apparent that refueling environment 10 may include multiple such dispenser positions configured in the illustrated manner. As known, dispenser position 12 serves as a refueling location where a customer may perform a refueling transaction. In one exemplary form, operator position 14 may include a point-of-sale (POS) terminal.

The illustrated dispenser position 12 includes a directional microphone system 16 having an array of individual directional microphones. Microphone system 16 may be provided in any suitable form for installation at dispenser position 12. For example, microphone system 16 may be implemented (along with its signal processing circuitry) as a stand-alone unit adapted for integration with dispenser position 12. Alternately, microphone system 16 may be integrally configured with the user-interactive terminal conventionally stationed at dispenser position 12.

One typical arrangement of dispenser position 12 utilizes a combined payment and dispenser terminal that enables a customer to furnish payment in the form of a credit or debit card purchase using a card reader module. However, this specific configuration of dispenser position 12 should not be seen in limitation of the present invention, as it should be apparent that the invention may be used with any suitable dispenser position arrangement.

The array of directional microphones that form microphone system 16 is suitably configured to define an acoustic coverage pattern that encompasses the space within which it is expected that vocal emanations from a refueling customer will originate and travel. For this purpose, the directional microphones are provided in an arrangement that maximizes the possibility of receiving customer speech and also takes into account the expected full range of movement of the customer while speaking. For purposes of simplicity, the coverage pattern may be viewed as a composite of the individual directional beam patterns associated with each of the directional microphones.

However, the composite beam pattern resulting from the microphone array should be fashioned so as also to minimize the possibility of capturing extraneous audio signals. Examples of unwanted audio include undue amounts of ambient background noise, sounds emanating from the customer vehicle, audio signals from adjacent dispenser positions, and other peripheral sounds present in the refueling environment.

Various forms of composite beam patterns may be developed based upon the anticipated position of the speaking customer. For example, a customer would typically stand no more than five (5) feet away from the microphone head. Generally, the acoustic coverage pattern need only contain the head of the customer (e.g., the front side) and the peripheral area extending between the head of the customer and the microphone unit.

It should be apparent that the spatial profile of the composite beam pattern generated by microphone system 16 may be produced according to conventional understandings of unidirectional acoustic beam technology. Several factors may be considered as part of the design effort in constructing the appropriate configuration of the directional microphone array, such as beam size, shape, position, and directionality.

In one form, the beam patterns of the individual directional microphones have a cardiod-shaped formation. The microphones may be suitably positioned relative to one another so as to create various overlaps among the individual acoustic beam patterns. For example, adjacent beam patterns will overlap in order to create a seamless, continuous and uninterrupted acoustic coverage area. In this manner, microphone system 16 can accommodate a certain limited amount of movement on the part of the customer without adversely affecting the audio reception. A composite beam pattern having such an overlap feature avoids any loss in reception that would occur with discontinuities in the coverage pattern.

An audio system based upon an array of directional microphones provides significant improvements over omni-directional microphone units. One distinguishing feature of microphone system 16 is that it is capable of precisely delimiting the space from which audio signals are detected and collected. By comparison, omni-directional reception will cause the collection of sounds that originate from sources other than the desired source, i.e., the customer. Additionally, omni-directional microphones acquire significantly more background noise than directional microphones.

In one optional form of the system shown in FIG. 1, some type of conventional notification means may be provided at dispenser position 12 to direct the customer to stand within a specific proximal relationship to the dispenser terminal and/or microphone head. Alternately, if a threshold level of unwanted sound is detected by the microphone signal processing facility, the customer will be directed to improve the reception by moving closer to the microphones, for example. Additionally, an insufficient detected audio signal will likewise result in the customer being prompted to take corrective action, such as when the customer is too far away or speaking too softly.

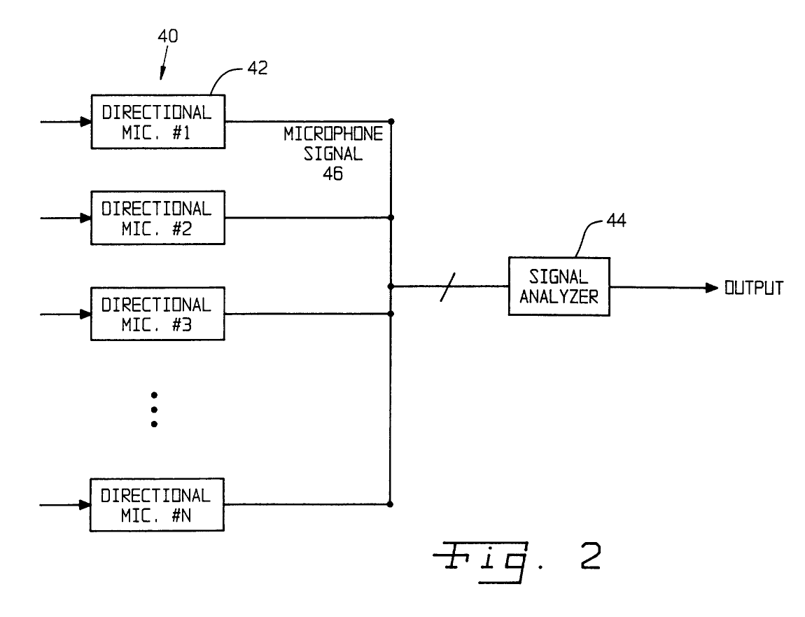

Referring again to FIG. 1, directional microphone system 16 is provided in combination with a processor 18 to process the signals generated by the array of directional microphones. Various exemplary forms of the processing function performed by processor 18 are discussed further in relation to FIG. 2.

Processor 18 generally performs any of various audio processing operations on the signals generated by the array of directional microphones. For this purpose, processor 18 may be provided in any suitable form known to those skilled in the art. The microphone signals will typically be provided in a corresponding electrical format representative of the audio signals detected by the directional microphones. Each microphone signal will typically be carried over a separate channel to processor 18, although any means may be provided to transport the signals (e.g., multiplexing).

Processor 18 should also be construed as embodying any type of pre-processing facility. For example, processor 18 may include, but is not limited to, an analog-to-digital converter (DAC), pre-amplification circuitry, and filter circuits. Various conventional filtering techniques may be used to remove spectral components from the audio signal representing unwanted audio, such as noise and non-speech signals, so that only voice signals remain for further processing.

Processor 18 may take advantage of advanced digital signal processing techniques. In one implementation, processor 18 will perform its processing operations using digital manipulations. For example, processor 18 may be provided in the form of an audio-related digital signal processor (DSP), software module, computer-related hardware and/or circuitry, firmware, an Application Specific Integrated Circuit (ASIC), a programmable general purpose computer, or any combination thereof.

Processor 18 may also include various conventional software routines and computer programs that embody the instructions for executing the signal processing operations. For example, software code may be provided to implement a Fast Fourier Transform (FFT) processing capability. The software code should be programmable and updatable to enable enhancements and modifications to be made to the signal processing functionality.

Referring still to FIG. 1, operator position 14 includes an operator facility 20 configured with a conventional speaker system 22. Operator facility 20 may be provided in any suitable form known to those skilled in the art, such as a POS terminal.

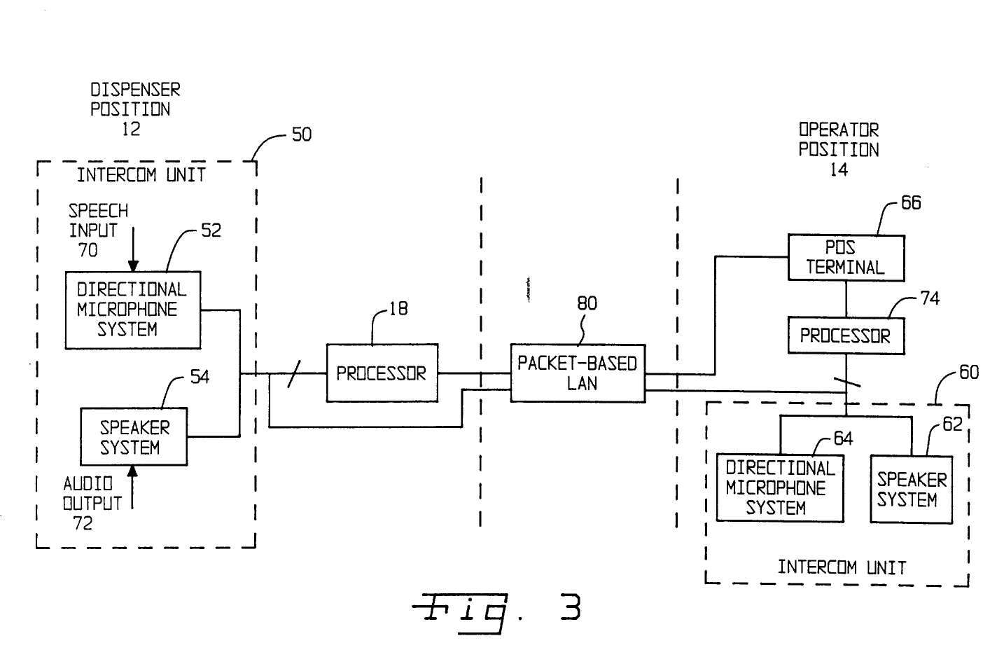

A communications link 24 enables communications between dispenser position 12 and operator position 14. Specifically, communications link 24 enables the processed microphone signals generated by processor 18 to be forwarded to operator position 14 for reproduction by speaker system 22, thereby enabling the customer to communicate with the station operator. As discussed further in connection with FIG. 3, dispenser position 12 and operator position 14 are both configured with a respective intercom system having a speaker-microphone combination. This intercom configuration enables bi-directional communication between the customer and operator over a suitable communications link 24.

It should be understood that communications link 24 may be provided in any suitable form. For example, link 24 may facilitate a wireline, wireless, optical, or other communications connection between dispenser position 12 and operator position 14. For this purpose, the relevant equipment will be included in conjunction with communications link 24 to facilitate the particular communications mode. For example, suitable RF transceivers and electro-optical converters would be needed to support a wireless and optical transport implementation, respectively.

Although operator position 14 is shown as part of refueling environment 10 (e.g., an on-site POS terminal), it should be understood that operator position 14 may be situated at locations other than the refueling site. For example, operator position 14 may be disposed remote from the refueling environment, such as at a remote management facility. For this purpose, communications link 24 will be adapted to facilitate this remote application.

Referring again to FIG. 1, dispenser position 12 conventionally includes a dispenser module 30 having fuel dispenser equipment 26 for dispensing fuel and a controller 28 for controlling the operation of dispenser equipment 26. For example, controller 28 may control the fuel pump in response to and in accordance with a corresponding command.

According to one optional form of the invention, controller 28 and/or fuel dispenser 26 are suitably adapted for use in combination with processor 18 so that dispenser module 30 may be configured as a voice-activatable device. More specifically, in a mode where dispenser position 12 is used to receive voice commands from a customer, processor 18 is suitably configured to process microphone signals from directional microphone system 16 and generate control-type command signals for use by controller 28.

The command signals are based upon and/or derived from voice instructions that are contained within the audio spectrum captured by the directional microphones. More particularly, these command signals are representative of various certain control instructions articulated by the customer and received by directional microphone system 16.

For this purpose, processor 18 will include a recognition facility to assist in recognizing and/or identifying the voice instruction embodied within the detected acoustic signals provided by microphone system 16. A conversion facility will be provided to translate the identified voice instruction into the corresponding command signal compatible with operation of controller 28. In this manner, a customer may direct controller 28 to carry out certain tasks by communicating the relevant control instruction into microphone system 16.

It is also possible to deploy the combination of directional microphone system and processor 18 in conjunction with any other type of voice-activatable system present at dispenser position 12 or at another location. For example, the illustrated system may be used in combination with a voice-activated, automated refueling assembly in which voice commands from the customer direct activation of the robotic equipment. The customer may also use voice commands to submit payment information into a voice-activatable payment terminal.

Reference is now made to FIG. 2, which depicts one illustrative configuration of directional microphone system 16 and processor 18 of FIG. 1 to facilitate a description of an illustrative signal processing function, according to another example of the invention. As shown, an array 40 of individual representative directional microphones 42 is connected to signal analyzer 44. The microphone signals 46 generated by directional microphones 42 are supplied to signal analyzer 44 for processing.

The processing functionality of signal analyzer 44 that defines the processing operations performed on microphones signals 46 is calculated generally to optimize acoustic reception of the voice communications emitted by the customer and detected by the directional microphone array 40.

In one exemplary form, the plural microphone signals 46 generated by the directional microphone array 40 are analyzed by signal analyzer 44 with a view towards determining which one of the microphone signals 46 optimally satisfies a predetermined performance criteria. For example, the microphone signals 46 may be evaluated on the basis of which signal provides the best signal-to-noise (S/N) ratio. However, any other type of acoustic performance evaluation may be used. Different performance analyses may be implemented in the same circuitry by reprogramming the software, for example, to execute a different or modified signal analysis routine.

Following completion of the acoustic performance evaluation, the optimal microphone signal is forwarded to its destination, e.g., operator position 14 in FIG. 1. In effect, a functional connection is made between the operator position and the particular directional microphone 42 that is associated with the optimal performance determination.

One notable feature of the processing function is that the microphone signals 46 continuously provided by microphone array 40 are dynamically and continuously evaluated to ensure that the optimal microphone signal is being sent to the operator facility. If signal analyzer 44 determines that the optimal microphone signal is now being received from a directional microphone different from the prior evaluation, a switch-like operation is executed to bring on-line the particular microphone that is associated with the current optimal performance determination. Thus, the functional connection between microphone array 40 and the operator facility may continuously change throughout the communications session. In this manner, a voice tracking feature is realized since the system is capable of making on-the-fly switches from one directional microphone to another depending upon the results of the performance evaluation.

In another exemplary form of signal analyzer 44, the processing function involves the formation of a composite signal based upon a weighted-sum combination of the individual microphone signals 46 received from the directional microphones 42. In this manner, the output signal from signal analyzer 44 includes a contribution from each of the detected acoustic signals respectively represented by microphone signal 46.

Additional descriptions of algorithmic approaches for analyzing the directional microphone signals may be found in U.S. Pat. Nos. 4,653,102 and 5,664,021, both incorporated herein by reference thereto.

Reference is now made to FIG. 3, which shows in block diagram format an illustrative configuration for a refueling environment employing intercom systems at the dispenser position and operator position, according to another example of the present invention.

The illustrated dispenser position 12 includes an intercom unit 50 having a directional microphone system 52 (similar to system 16 in FIG. 1) and a speaker system 54 of conventional form. The illustrated operator position 14 includes an intercom unit 60 having a speaker system 62 of conventional form and a microphone system 64 preferably of the type disclosed herein having an array of directional microphones. The operator intercom unit 60 is operatively associated with a POS terminal 66 provided at operator position 14.

In this configuration, bi-directional voice communications are possible between the customer using intercom unit 50 and the station operator using intercom unit 60 at POS terminal 66. In particular, voice communications from a customer are provided as speech input 70 to microphone system 52 of dispenser intercom 50 and subsequently directed to speaker system 62 of operator intercom 60. Similarly, voice communications from a station operator are detected by microphone system 64 of operator intercom 60 and subsequently directed to speaker system 54 of dispenser intercom 50 for reproduction as audio output 72.

As shown, dispenser position 12 includes processor 18 as described in connection with FIGS. 1 and 2 for processing the microphone signals generated by directional microphone system 52. Processor 18 may also provide processing of signals being directed to dispenser speaker system 54 from operator microphone system 64. For example, in digital implementations, a D/A conversion may be needed. The operator position 14 likewise includes a processor 74 similar in form and functionality to processor 18. In particular, processor 74 processes the microphone signals generated by directional microphone system 64.

In one optional form of the system, the communications link between dispenser position 12 and operator position 14 is provided in the form of a packet-based local area network (LAN) 80. Voice communications between dispenser intercom 50 and operator intercom 60 will be carried over this link. For this purpose, processor 18 and processor 74 will be suitably configured to handle the communications format of LAN 80, both in regards to the transmission and reception of signals in conjunction with LAN 80.

In one exemplary form, LAN 80 will employ an Internet Protocol (IP) specification format. In this manner, the refueling environment can be connected to the Internet and/or World Wide Web to enable dispenser intercom 50 and/or operator intercom 60 to connect with various Internet resources, e.g., servers. In general, the IP format of LAN 80 provides a Voice over Internet Protocol (VoIP) functionality that facilitates the connection of dispenser intercom 50 and/or operator intercom 60 to any of various local and remote data networks.

While this invention has been described as having a preferred design, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

What is claimed is:

1. A system for use with a fuel dispenser position in a refueling environment, said system comprising:
a microphone assembly disposed at said fuel dispenser position;
said microphone assembly including a plurality of directional microphones; and
a processing assembly operatively associated with said microphone assembly, said processing assembly being configured to process signals operatively generated by the directional microphones of said microphone assembly.

2. The system as recited in claim 1, wherein said processing assembly being configured to form a composite signal using signals from at least two directional microphones of said microphone assembly.

3. The system as recited in claim 2, further comprises:
an operator facility; and
a means to direct the composite signal formed by said processing assembly to said operator facility.

4. The system as recited in claim 1, wherein said processing assembly being configured to determine which microphone signal among the signals operatively generated by the directional microphones of said microphone assembly optimally satisfies a predetermined performance criteria.

5. The system as recited in claim 4, further comprises:
an operator facility; and
a means to direct the microphone signal operatively associated with the optimal performance determination made by said processing assembly to said operator facility.

6. The system as recited in claim 1, further comprises:
an operator facility including a plurality of directional microphones; and
a coupling means to provide operative coupling between said operator facility and said fuel dispenser position to enable communication therebetween.

7. The system as recited in claim 6, further comprises:
a first speaker system disposed at said fuel dispenser position; and
a second speaker system disposed at said operator facility.

8. The system as recited in claim 7, wherein said coupling means being configured to enable communication between the directional microphones of said microphone assembly and said second speaker system, and to enable communication between the directional microphones of said operator facility and said first speaker system.

9. The system as recited in claim 1, further comprises:
a fuel dispenser apparatus disposed at said fuel dispenser position; and
a dispenser controller configured to operatively control said fuel dispenser apparatus in response to at least one command signal;
wherein said processing assembly being configured further to operatively process at least one microphone signal and to generate therefrom at least one command-type signal for use by said dispenser controller.

10. The system as recited in claim 1, further comprises:
a voice-activatable fuel dispenser system disposed at said fuel dispenser position and operatively associated with said microphone assembly.

11. The system as recited in claim 1, further comprises:
a packet-based data network configured for connection to at least one of said microphone assembly and said processing assembly.

12. The system as recited in claim 1, wherein said processing assembly being configured further to operatively provide processed microphone signals in an Internet Protocol (IP) format.

13. The system as recited in claim 1, wherein the directional microphones of said microphone assembly being arranged to define a desired acoustic coverage pattern.

14. A system, comprising:
a refueling environment including a fuel dispenser position, said fuel dispenser position including a microphone system;
said microphone system including a plurality of directional microphones;
an operator facility in said refueling environment; and
a coupling means configured to provide operative coupling between said fuel dispenser position and said operator facility.

15. The system as recited in claim 14, further comprises:
a processing system configured to process signals operatively generated by the directional microphones of said microphone system.

16. The system as recited in claim 15, wherein said processing system being configured further to form a composite signal using signals from at least two directional microphones of said microphone system.

17. The system as recited in claim 16, further comprises:
a means to direct the composite signal to said operator facility using said coupling means.

18. The system as recited in claim 15, wherein said processing system being configured further to determine which microphone signal among the signals operatively generated by the directional microphones of said microphone system optimally satisfies a predetermined performance criteria.

19. The system as recited in claim 18, further comprises:
a means to direct the microphone signal operatively associated with the optimal performance determination made by said processing system to said operator facility.

20. The system as recited in claim 14, wherein said operator facility further comprises:
a plurality of operator-related directional microphones.

21. The system as recited in claim 20, wherein said operator facility further comprises:
a processing unit configured to process signals operatively generated by said plurality of operator-related directional microphones.

22. The system as recited in claim 21, wherein said processing unit being configured further to form a composite signal using signals from at least two operator-related directional microphones.

23. The system as recited in claim 22, further comprises:
a means to direct the composite signal to said fuel dispenser position using said coupling means.

24. The system as recited in claim 21, wherein said processing unit being configured further to determine which microphone signal among the signals operatively generated by the operator-related directional microphones optimally satisfies a predetermined performance criteria.

25. The system as recited in claim 24, further comprises:
a means to direct the microphone signal operatively associated with the optimal performance determination made by said processing unit to said fuel dispenser position.

26. The system as recited in claim 14, wherein said operator facility includes a point-of-sale (POS) terminal.

27. The system as recited in claim 14, further comprises:
a voice-activatable fuel dispenser system disposed at said fuel dispenser position and operatively associated with said microphone system.

28. A system for use in a refueling environment having a fuel dispenser position and an operator facility, said system comprising:
a dispenser intercom system disposed proximate said fuel dispenser position, said dispenser intercom system including a first speaker system and a first microphone system;
said first microphone system comprising a plurality of directional microphones;
an operator intercom system disposed proximate said operator facility, said operator intercom system including a second speaker system and a second microphone system; and
a coupling means configured to provide operative coupling between said dispenser intercom system and said operator intercom system.

29. The system as recited in claim 28, further comprises:
a first processor operatively associated with said dispenser intercom system, said first processor being configured to process signals operatively generated by the directional microphones of said first microphone system.

30. The system as recited in claim 29, wherein said first processor being configured further to form a composite signal using signals from at least two directional microphones of said first microphone system, and to direct the composite signal to said operator intercom system using said coupling means.

31. The system as recited in claim 29, wherein said first processor being configured further to determine which microphone signal among the microphone signals operatively generated by said first microphone system optimally satisfies a predetermined performance criteria, and to direct the microphone signal operatively associated with the optimal performance determination to said operator intercom system using said coupling means.

32. The system as recited in claim 29, wherein said first processor being configured further to operatively provide processed microphone signals in an Internet Protocol (IP) format.

33. The system as recited in claim 29, further comprises:
a fuel dispenser apparatus disposed at said fuel dispenser position; and
a dispenser controller configured to operatively control said fuel dispenser apparatus in response to at least one command signal;
wherein said first processor being configured further to process at least one microphone signal operatively generated by said first microphone system and to generate therefrom at least one command-type signal for use by said dispenser controller.

34. The system as recited in claim 28, wherein said second microphone system includes a plurality of directional microphones.

35. The system as recited in claim 34, further comprises:
a second processor operatively associated with said operator intercom system, said second processor being configured to process signals operatively generated by the directional microphones of said second microphone system.

36. The system as recited in claim 35, wherein said second processor being configured further to form a composite signal using signals from at least two directional microphones of said second microphone system, and to direct the composite signal to said dispenser intercom system using said coupling means.

37. The system as recited in claim 35, wherein said second processor being configured further to determine which microphone signal among the microphone signals operatively generated by said second microphone system optimally satisfies a predetermined performance criteria, and to direct the microphone signal operatively associated with the optimal performance determination to said dispenser intercom system using said coupling means.

38. The system as recited in claim 35, wherein said second processor being configured further to operatively provide processed microphone signals in an Internet Protocol (IP) format.

39. The system as recited in claim 28, wherein said operator facility includes a point-of-sale (POS) terminal.

40. The system as recited in claim 28, wherein said coupling means includes a packet-based data network.

41. The system as recited in claim 28, further comprises:
a voice-activatable fuel dispenser system disposed at said fuel dispenser position and operatively associated with said first microphone system.

42. A system for use in a refueling environment having a fuel dispenser position and also for use in combination with an operator facility, said system comprising:
a first communication system disposed at said fuel dispenser position, said first communication system including a first microphone system and a first speaker system;
said first microphone system including a plurality of directional microphones; and
a communications link configured to enable operative communications between said first communication system and said operator facility.

43. The system as recited in claim 42, wherein said communications link being configured further to enable said first microphone system to transmit microphone signals operatively generated thereby to said operator facility, and to enable said first speaker system to receive audio-related signals from said operator facility.

44. The system as recited in claim 42, further comprises:
a voice-activatable fuel dispenser system disposed at said fuel dispenser position and operatively associated with said first microphone system.

45. The system as recited in claim 42, wherein said communications link includes a packet-based data network.

46. The system as recited in claim 42, wherein said operator facility being disposed remote from said refueling environment.

47. The system as recited in claim 42, wherein said operator facility being disposed in said refueling environment and including a point-of-sale (POS) terminal.

48. The system as recited in claim 42, wherein said operator facility includes a plurality of directional microphones.

49. The system as recited in claim 42, further comprises:
a first processor operatively associated with said first communication system, said first processor being configured to process signals operatively generated by the directional microphones of said first microphone system in accordance with a predetermined processing function.

50. The system as recited in claim 49, wherein the predetermined processing function performed by said first processor being defined by the formation of a composite signal using signals from at least two directional microphones of said first microphone system.

51. The system as recited in claim 49, wherein the predetermined processing function performed by said first processor being defined by a determination of which microphone signal among the signals operatively generated by the directional microphones of said first microphone system optimally satisfies a predetermined performance criteria.
